(19) United States
(12) Patent Application Publication
(10) Pub. No.: US 2014/0190560 A1
(43) Pub. Date: Jul. 10, 2014

(54) BACK-SIDE ELECTRODE OF P-TYPE SOLAR CELL

(71) Applicant: E I DU PONT DE NEMOURS AND COMPANY, Wilmington, DE (US)

(72) Inventors: AKIRA INABA, Kawasaki-shi (JP); Takeshi Kondo, Kanagawa (JP)

(73) Assignee: E I DU PONT DE NEMOURS AND COMPANY, Wilmington, DE (US)

(21) Appl. No.: 13/737,091

(22) Filed: Jan. 9, 2013

(51) Int. Cl. H01L 31/18; H01L 31/0224

(52) U.S. Cl. CPC H01L 31/18; H01L 31/022441
USPC 136/256; 438/98

(57) ABSTRACT

A back-side aluminum electrode adjacently formed on silicon wafer of p-type solar cell, comprising, (a) first aluminum layer and (b) second aluminum layer, wherein (a) first aluminum layer formed adjacent to the silicon wafer, formed from first aluminum paste comprises aluminum powder and glass frit, wherein the weight ratio of the glass frit for the aluminum powder (glass/aluminum) is 0.02-1.0, and wherein (b) second aluminum layer formed adjacent to the first aluminum layer, formed from second aluminum paste comprises at least aluminum powder, wherein the weight ratio (glass/aluminum) of the second aluminum paste is less than the weight ratio(glass/aluminum) of the first aluminum paste.

### FIELD OF THE INVENTION

The present invention is directed to a back-side electrode formed on silicon layer of p-type solar cell.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate hole-electron pairs in that body. The potential difference that exists at a p-n junction causes holes and electrons to move across the junction in opposite directions and thereby give rise to flow of an electric current that is capable of delivering power to an external circuit. Most solar cells are in the form of a silicon wafer that is metallized, i.e., provided with metal contacts which are electrically conductive.

During the formation of a silicon solar cell, an aluminum paste is generally screen printed and dried on the back-side of the silicon wafer. The wafer is then fired at a temperature above the melting point of the eutectic point of aluminum and silicon to form an aluminum-silicon melt. Subsequently, during the cooling phase, an epitaxially grown layer of silicon is formed that is doped with aluminum. This layer is generally called the back surface field (BSF) layer, and helps to improve the energy conversion efficiency of the solar cell.

Most electric power-generating solar cells currently used are silicon solar cells. Process flow in mass production is generally aimed at achieving maximum simplification and minimizing manufacturing costs. Electrodes in particular are made by using a method such as screen printing from a metal paste.

An example of this method of production is described below in conjunction with FIG. 1. FIG. 1A shows a p-type silicon substrate 10. In FIG. 1B an n-type diffusion layer 20 of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer 20 is formed over the entire surface of the silicon substrate 10. The p-n junction is formed where the concentration of the p-type dopant equals the concentration of the n-type dopant; conventional cells that have the p-n junction close to the sun side, have a junction depth between 0.05 and 0.5 μm. After formation of this diffusion layer, excess surface glass is removed from the rest of the surfaces by etching by an acid such as hydrofluoric acid in the manner shown in FIG. 1C. Next, an antireflective coating (ARC) 30 is formed on the n-type diffusion layer 20, to a thickness of between 0.05 and 0.1 μm in the manner shown in FIG. 1D by a process, such as, for example, plasma chemical vapor deposition (CVD). As shown in FIG. 1E, a front-side silver paste (front electrode-forming silver paste) 500, for the front electrode is screen printed and then dried over the antireflective coating 30. In addition, a back-side aluminum paste 60 and back-side silver or silver/aluminum paste 70 are then screen printed (or some other application method) and successively dried on the back-side of the substrate. Conventionally, the back-side silver paste 70 is screen printed onto the silicon first as two parallel strips (busbars) or as rectangles (tabs) ready for soldering interconnection strings (presoldered copper ribbons), the aluminum paste 60 is then printed in the bare areas with a slight overlap over the back-side silver 70. In some cases, the silver paste 60 is printed after the aluminum paste 70 has been printed. Firing is then typically carried out in a belt furnace for a period of 1 to 5 minutes with the wafer reaching a peak temperature in the range of 600 to 900° C. The front and back electrodes can be fired sequentially or cofired.

Consequently, as shown in FIG. 1F, molten aluminum from the paste dissolves the silicon during the firing process and then on cooling forms an eutectic layer that epitaxially grows from the silicon base 10, forming a p+ layer 40 containing a high concentration of aluminum dopant. This layer is generally called the back surface field (BSF) layer, and helps to improve the energy conversion efficiency of the solar cell. A thin layer of aluminum is generally present at the surface of this epitaxial layer.

In recent years, attention has been focused on improving the ability of silicon substrates for solar cells to convert solar energy into electrical energy, and a variety of attempts have been made to improve the electrical characteristics, such as the open circuit voltage (Voc), of back-side aluminum electrode films. For example, attempts have been made to improve electrical characteristics by incorporating glass in an aluminum paste used to form a back-side aluminum electrode film, as disclosed in U.S. Pat. No. 7,771,623. However, as a result of further technological advances, even higher electrical characteristics are now required.

### SUMMARY OF THE INVENTION

In one aspect, the present invention relates to a back-side aluminum electrode adjacently formed on silicon wafer of p-type solar cell, comprising, (a) first aluminum layer and (b) second aluminum layer, wherein (a) first aluminum layer formed on the silicon wafer, formed from first aluminum paste comprising aluminum powder and glass frit, wherein weight ratio of the glass frit for the aluminum powder (glass/aluminum) is 0.02-1.0, and wherein (b) second aluminum layer formed on the first aluminum layer, formed from second aluminum paste comprising at least aluminum powder, wherein weight ratio (glass/aluminum) of the second aluminum paste is less than the weight ratio (glass/aluminum) of the first aluminum paste.

### BRIEF DESCRIPTION OF THE FIGURES

FIG. 1A-1F show a process flow diagram illustrating exemplary the fabrication of a silicon solar cell.

FIG. 1A shows a sectional view of p-type silicon substrate. FIG. 1B shows n-type diffusion layer was formed on the p-type silicon substrate. FIG. 1C shows the excess surface glass of the n-type diffusion layer was removed from the rest of the surfaces by etching. FIG. 1D shows a sectional view of antireflective coat formed on the n-type diffusion layer. FIG. 1E shows a sectional view of front-side silver paste screen formed over the antireflective coat. FIG. 1F shows a sectional view of BSF layer, formed on silicon substrate.

FIG. 2A-2D explains the manufacturing process for manufacturing a silicon solar cell having a back-side aluminum electrode.

FIG. 2A shows a sectional view of Si substrate and electrodes formed on the light-receiving side of the Si substrate. FIG. 2B shows aluminum paste 106 for back-side electrodes printed on the Si Substrate 102. Aluminum paste 106a comprises aluminum powder, glass frit and the weight ratio of the glass frit for the aluminum powder (glass/aluminum) is 0.02-1.0. Aluminum paste 106b comprises aluminum powder, glass frit and the weight ratio (glass/aluminum) of the aluminum paste 106b is less than the weight ratio (glass/aluminum) of the aluminum paste 106a. FIG. 2C shows an embodiment where both Al paste 106 and Ag paste 108 were printed. FIG. 2D shows the obtained solar cell.

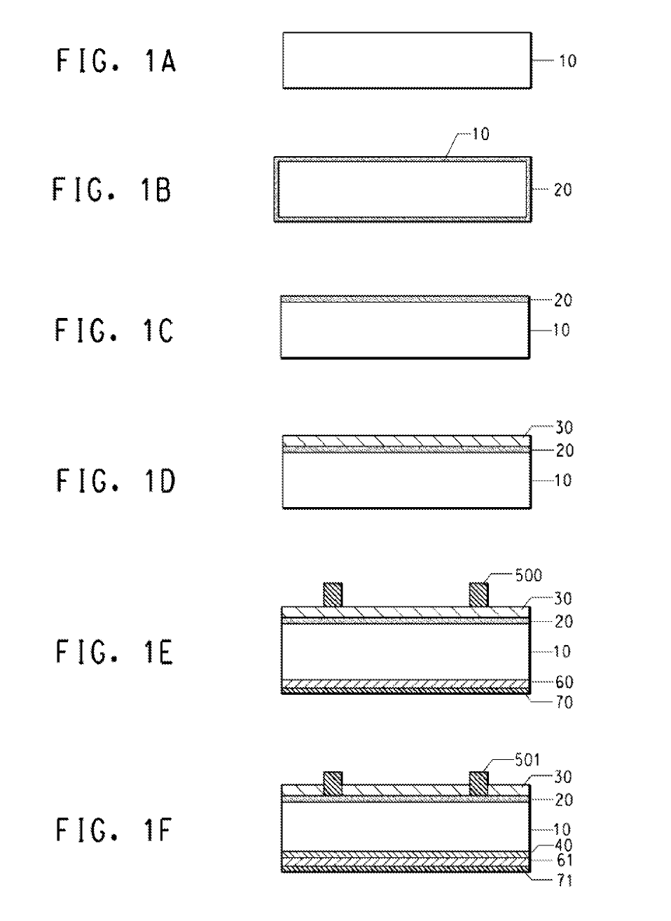

### DETAILED DESCRIPTION OF THE INVENTION

The present invention is explained in detail below.

### (Back-Side Electrode)

The back-side aluminum electrode is formed adjacently on silicon wafer of p-type solar cell. The back-side aluminum electrode comprises (a) first aluminum layer formed on the silicon wafer, formed from first aluminum paste and (b) second aluminum layer formed on the first aluminum layer, formed from second aluminum paste.

In this way, the back-side aluminum electrode includes two layers, namely a first layer provided on a silicon substrate and a second layer provided on the first layer. As mentioned later, the content of glass in the first aluminum paste used to form the first layer is not lower than 0.02 and not higher than 1.0 in terms of weight ratio (glass/aluminum) relative to the aluminum powder. Furthermore, the aforementioned weight ratio (glass/aluminum) in the second aluminum paste used to form the second layer is lower than the aforementioned weight ratio (glass/aluminum) in the first aluminum paste used to form the aforementioned first layer. In the present invention, a layer having high glass content is provided on a silicon substrate in an aluminum electrode and a separate layer having low glass content is provided on the aforementioned layer, thereby providing a back-side aluminum electrode that exhibits excellent electrical characteristics.

### (a) First Aluminum Layer

In one embodiment, first aluminum layer is formed from first aluminum paste comprising aluminum powder and glass frit, wherein the weight ratio of the glass frit for the aluminum powder (glass/aluminum) is 0.02 to 1.0.

### First Aluminum Paste

### Aluminum Powder

In one embodiment, the first aluminum paste comprises aluminum powder. The aluminum powder comprises atomized aluminum in an embodiment. The atomized aluminum may be atomized in either air or inert atmosphere. In one embodiment, the average particle size distribution of the atomized aluminum powder is in the range of 0.5 to 20 μm. In one embodiment, the average particle size distribution of the aluminum powder is in the range of 1 to 10 μm. The form of the aluminum powder is not particularly limited, but a spherical or flake form or the like is preferred. In the present disclosure, the aluminum powder is one which contains aluminum metal in the amount of 85 wt % or more of the powder. In further embodiment, the aluminum powder may be further accompanied by other additive materials, such as, Mg, Ti, Cr, Mo, W, Mn, Ni, Cu, Ag, Zn, Si, Bi, Sb, Fe or a mixture thereof. In one embodiment, the content of the aluminum powder in the aluminum paste is preferably 60 to 85 wt %. In another embodiment, the content is preferably 65 to 80 wt %.

In another embodiment, the content is preferably 70 to 80 wt %. If the content is less than 60 wt %, a good BSF layer may not be formed because the film thickness becomes smaller after the aluminum paste is printed, resulting in an insufficient reaction phase between the silicon and aluminum. If the content is over 85 wt %, on the other hand, a suitable viscosity for printing may not be obtained.

### Glass Frit

Generally, the function of the glass frit in an aluminum paste is primarily to provide a means to increase the efficiency by which the silicon is accessed by the molten aluminum during the firing process. In addition to this function, glass frit provides some additional cohesion and adhesion properties to the substrate. The glass frit affects the bowing of the aluminum layer in the finished cell. The glass frit can also increase the alloying depth of the aluminum into the silicon, therefore enhancing or increasing the aluminum silicon layer. The glass frit is, in one embodiment, chosen based on the effectiveness that they have on improving the electrical performance of the aluminum paste without compromising other considerations such as environmental legislation or public desire to exclude heavy metals of potential environmental concern.

In the present invention, as aforementioned, the weight ratio of the glass frits for the aluminum powder (glass/aluminum) in the first aluminum paste is equal to or more than 0.02, before firing. In another embodiment, the weight ratio is from 0.02 to 1.0, before firing. If the weight ratio of the glass frits for the aluminum powder (glass/aluminum) is lower than 0.02, the eutectic reaction between the aluminum and the silicon wafer does not occur sufficiently and a good BSF layer is not formed. However, if the weight ratio of the glass frits for the aluminum powder (glass/aluminum) exceeds 1.0, the resistance of the back-side aluminum electrode increases. In either of these cases, good electrical characteristics cannot be achieved. Useful glass frit is known in the art. Some examples include borosilicate and aluminosilicate glasses. Specifically, it is possible to use a glass frit having B₂O₃—SiO₂-based, Bi₂O₃-based or B₂O₃—SiO₂—PbO-based glass composition that contains, for example, a group IV-A element such as Ti or Zr, a group V-A element such as V, Nb or Ta, a group I-B element such as Ag or Cu, a group II-B element such as Zn or Cd, a group III-B element such as Al, Ga or In or a group I-B element such as Ge or Sn in addition to an alkali metal or alkaline earth metal oxide or fluoride. It is possible to use one or two or more types of these glass frits in the aluminum paste.

The preparation of such glass frit composition is well known and consists, for example, in melting together the constituents of the glass in the form of the oxides of the constituents and pouring such molten composition into water to form the frit. The batch ingredients may, of course, be any compounds that will yield the desired oxides under the usual conditions of frit production. The glass is preferably milled in a ball mill with water or inert low viscosity, low boiling point organic liquid to reduce the particle size of the frit and to obtain a frit of substantially uniform size. It is then settled in water or said organic liquid to separate fines and the supernatant fluid containing the fines is removed. Other methods of classification may be used as well.

In one embodiment, the glass transition temperature (Tg) of the aforementioned glass frit is not higher than 577° C., which is starting temperature of the eutectic reaction between the aluminum and the silicon. If the aforementioned glass transition temperature is higher than the aforementioned starting temperature of the eutectic reaction, the electrical characteristics deteriorate due to the sintering of the aluminum powder or the eutectic reaction between the aluminum and the silicon being inhibited. Here, in the specification, the glass transition temperature is the temperature at which an amorphous solid becomes soft upon heating or brittle upon cooling. The glass transition temperature is measured by DTA.

In addition, in the specification, the starting temperature of the eutectic reaction is the lowest temperature at which the mixture of aluminum and silicone, having eutectic system, will start melting.

In one embodiment, the average particle size (D50) of the glass frit composition is 0.1-8 μm. The reason for this is that smaller particles having a high surface area tend to adsorb the organic materials and thus impede clean decomposition. On the other hand, larger size particles tend to have poorer sintering characteristics.

Organic Medium and Additives

In one embodiment, the first aluminum paste may comprise organic medium and other organic additives, such as, surfactants, thickeners, rheology modifiers and stabilizers as explained below as additives.

A wide variety of inert viscous materials can be used as organic medium. The rheological properties of the organic medium must be such that they lend good application properties to the composition, including: stable dispersion of solids, appropriate viscosity and thixotropy for screen printing, appropriate wettability of the substrate and the paste solids, a good drying rate, and good firing properties. The organic vehicle which can be used in the first aluminum paste is preferably a nonaqueous inert liquid. The organic medium is typically a solution of polymer(s) in solvent(s). Additionally, a small amount of additives, such as surfactants, may be a part of the organic medium. The most frequently used polymer for this purpose is ethyl cellulose. Other examples of polymers include ethylhydroxyethyl cellulose, wood rosin, mixtures of ethyl cellulose and phenolic resins, polymethacrylates of lower alcohols, and monobutyl ether of ethylene glycol monoacetate can also be used. The most widely used solvents are ester alcohols and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. In addition, volatile liquids for promoting rapid hardening after application on the substrate can be included in the vehicle. Various combinations of these and other solvents are formulated to obtain the viscosity and volatility requirements desired.

The content of polymer present in the organic medium is in the range 0.5 weight percent to 11 weight percent of the total composition. The first aluminum paste used in the present invention may be adjusted to a predetermined, screen-printable viscosity with the organic polymer containing medium.

In one embodiment, the content (wt %) of the organic medium is 17 to 70 wt % per 100 wt % of the aluminum powder. In another embodiment, the content (wt %) of the organic medium is preferably 25 to 40 wt % per 100 wt % of the aluminum powder. If the content (wt %) is less than 17 wt % per 100 wt % of the aluminum powder, a suitable viscosity for printing may not be obtained. On the other hand, if the content (wt %) is over 70 wt % per 100 wt % of the aluminum powder, a good BSF layer may not be formed because the film thickness will be smaller after the aluminum paste is printed, resulting in an insufficient reaction phase between the silicon and aluminum.

The first aluminum paste may further comprise one or more other organic additives, such as, surfactants, thickeners, rheology modifiers and stabilizers. The organic additive(s) may be part of the organic medium. However, it is also possible to add the organic additive(s) separately when preparing the aluminum pastes. The organic additive(s) may be present in the aluminum pastes of the present invention in a total proportion of, for example, 0 to 10 wt %, based on total aluminum paste composition.

The conductive component (aluminum paste) explained above is typically conveniently manufactured by mechanically mixing, a dispersion technique that is equivalent to the traditional roll milling. Roll milling or other mixing technique can also be used. The conductive component is preferably spread on the desired part of the back face of a solar cell by screen printing; in spreading by such a method, it is preferable to have a viscosity in a prescribed range. Other application methods can be used such as silicone pad printing. The viscosity of the aluminum paste is preferably 20-100 Pa·s when it is measured at a spindle speed of 10 rpm and 25° C. by a utility cup using a Brookfield HBT viscometer and #14 spindle.

### (b) Second Aluminum Layer

In one embodiment, second aluminum layer is formed from second aluminum paste comprising at least aluminum powder, wherein the weight ratio (glass/aluminum) of the second aluminum paste is less than the weight ratio (glass/aluminum) of the first aluminum paste.

The aluminum powder, glass frit, and additives in the second aluminum paste, which is used to form the aforementioned second aluminum layer, are the same as those mentioned in relation to the aforementioned first aluminum layer. In addition, the (glass/aluminum) weight ratio of second aluminum paste is less than that of the first aluminum paste. In the present invention, by imparting a back-side aluminum layer with a two-layer constitution comprising the first layer and the second layer, where the first layer is formed on the silicon wafer, having larger (glass/aluminum) weight ratio c compared to the second layer formed on the first layer, it becomes possible to provide a solar cell which has a sufficient glass content in the back-side aluminum layer as a whole and which has an excellent open circuit voltage and EFF (conversion efficiency). In one embodiment, the (glass/aluminum) weight ratio in the second layer is lower than the (glass/aluminum) weight ratio in the aforementioned first layer, and preferably falls within the range 0.01-0.3. In addition, in another embodiment, the weight ratio in the second layer preferably falls within the range 0.01-0.25.

### (Solar Cell)

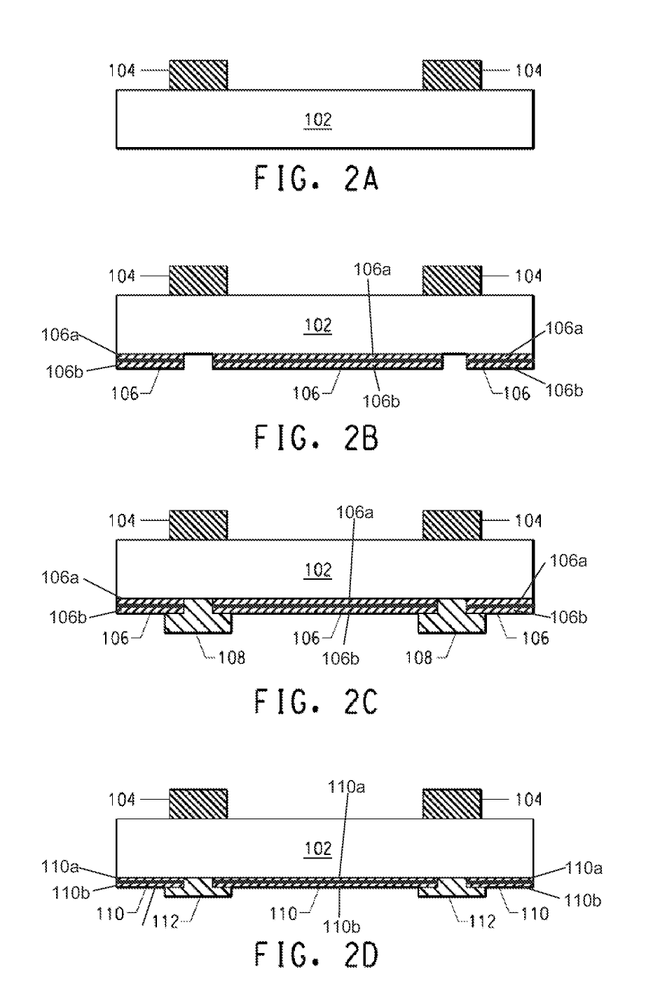

Next, an example in which a p-type solar cell having a back-side aluminum electrode of the present invention is prepared using the above aluminum pastes is explained, referring to the Figure (FIG. 2).

First, a Si substrate 102 is prepared. On the light-receiving side face (surface) of the Si substrate, normally with the p-n junction close to the surface, electrodes, for example, electrodes mainly composed of Ag 104, are installed (FIG. 2A).

On the back-side of the substrate, the conductive component (aluminum paste) used for forming a back-side electrode of p-type solar cell of the present invention is spread, for example, by screen printing in a pattern (FIG. 2B). Here, FIG. 2B shows aluminum paste 106 for back-side electrodes printed on the Si Substrate 102. Aluminum paste 106a, which is used for the first aluminum layer, comprises aluminum powder, glass frit and the weight ratio of the glass frit for the aluminum powder (glass/aluminum) is equal to or more than 0.02. And as for aluminum paste 106b, the weight ratio (glass/aluminum) of the paste is less than the weight ratio (glass/aluminum) of the aluminum paste 106a as aforementioned.

Here, when forming the aluminum layer by coating the aluminum paste on the back-side of the Si substrate, said aluminum paste may be coated on the entire back-side of the Si substrate or, in cases where the back-side of the Si substrate is partially covered by a passivation layer of Si₃N₄, Al₂O₃, or TiO₂, may be coated on this passivation layer. In this case, the aforementioned passivation layer may be formed at a thickness of 0.01-0.5 μm by a CVD method. Then, Ag paste 108 is spread by screen printing using the pattern that enable slight overlap with the back-side aluminum paste 106b referred to above (FIG. 2C), then dried. The drying temperature of each paste is preferably 150° C. or lower in drier for 5-10 minutes.

In one embodiment, the aluminum paste has a dried film thickness of 5-30 μm. In another embodiment, the thickness of the aluminum paste is 8-25 μm. Also, the overlapped width of the aluminum paste and the silver electrode conductive paste is preferably about 0.5-2.5 mm. Next, the substrate obtained is fired at a temperature of 600-900° C. for about 1 min-15 min, for instance, so that the desired solar cell is obtained (FIG. 2D). An electrode is formed from the pastes wherein said composition has been fired to remove the organic medium and sinter the glass frit. The solar cell obtained using the aforementioned aluminum paste, as shown in FIG. 2D has electrodes 104 on the light-receiving face (surface) of the substrate (for example, Si substrate) 102, Aluminum electrodes 110, comprising first alumium layer 110a formed from Aluminum paste 106a and second alumium layer 110b formed from Aluminum paste 106b, and electrodes 112 formed from Ag paste on the back face of the substrate 102.

In one embodiment, the thickness of the back-side aluminum electrode is equal to or more than 10.0 μm, equal to or more than 12.0 μm in another embodiment. If the aforementioned film thickness is 10 μm or lower, a BSF having good performance cannot be formed and a deterioration in open circuit voltage, conversion efficiency (Eff %) and so on may occur.

The present invention will be discussed in further detail by giving practical examples. The scope of the present invention, however, is not limited in any way by these practical examples.

### EXAMPLE

Solar cells were formed as follows:

### (1) Manufacturing

(i) Aluminum Paste(s) Preparation

The aluminum paste was produced using the following materials.

### Materials

(a) Aluminum powder: (The average particle size distribution of the aluminum-containing powder (D50)=5 μm)
(b) Glass frits: (Glass composed primarily of SiO₂—B₂O₃—Bi₂O₃—ZnO, with BaO, Al₂O₃ and the like added thereto, the glass transition temperature=460° C.)
(c) Organic medium: (Resin solution comprising ethyl cellulose resin dissolved in terpineol)

### Procedure of the Preparations

Aluminum paste preparations (first aluminum paste and second aluminum paste) were accomplished with the following procedure.

As for the first aluminum paste (used for the first aluminum layer), aluminum powder, glass frit described in the corresponding columns of Table 1 were dispersed in the organic medium and mixed by mixer for 120 minutes. The contents of the aluminum powder and the glass frit were shown in Table 1. The degree of dispersion was measured by fineness of grind (FOG). Atypical FOG value was generally equal to or less than 20/10 for a conductor. Likewise, the second aluminum pastes (used for the second aluminum layer) were prepared. The contents of the aluminum powder and the glass frit were shown in Table 1.

(ii) Solar Cell Preparation (Sample Preparation)

On the front-side of a Si substrate (200 μm thick multicrystalline silicon wafer of area 14.44 cm² p-type (boron) bulk silicon, with an n-type diffused POCl₃ emitter, surface texturized with acid, SiNₓ anti-reflective coating (ARC) on the wafer's emitter applied by CVD), silver pastes (PV159 Ag composition commercially available from E. I. Du Pont de Nemours and Company) were printed and dried so as to form front-side electrodes having 20 μm thickness. Then, aluminum pastes for the back-side electrode of solar cell, prepared in (i) were screen-printed. The screen-printed aluminum pastes were dried before firing.

The printed wafers were then fired in a Dispatch furnace at a belt speed of 550 cm/min. The wafers reached a peak temperature of 740° C. After firing, the metalized wafer became a functional photovoltaic device. The thickness of the Al layers of the samples (Examples 1-7 and Comparative Examples 1-3) after drying were shown in Table 1.

### (2) Test Procedures-Electric Performance

### 2-1) Measurement of Open Circuit Voltage (Voc)

Each sample of solar cells (Examples 1-7 and Comparative Example 1-3) formed according to the method described above were placed in a commercial I-V tester (supplied by NPC.) for the purpose of measuring light conversion efficiencies. The lamp in the I-V tester simulated sunlight of a known intensity (approximately 1000 W/m²) and illuminated the emitter of the cell. The electrodes formed on the fired cells were contacted by four electrical probes. The photocurrent (Voc, open circuit voltage; Isc, short circuit current) generated by the solar cells was measured over arrange of resistances to calculate the I-V response curve. Voc values were subsequently derived from the I-V response curve.

### 2-2) Evaluation Based on Open Circuit Voltage Value (Voc)

The Voc values obtained from the sample measurements for each example as described above were evaluated in comparison with the open circuit voltage value (Voc) obtained from the sample measurements of Comparative Example 1. The results are shown in Table 1.

TABLE 1

| | | | | | | | | | Thickness of AL | | |
|---|---|---|---|---|---|---|---|---|---|---|---|
| | first aluminum paste | | | | second aluminum paste | | | | layers(electrode)(μm) | | |
| | | Glass | Weight Ratio | Organic | | Glass | Weight Ratio | Organic | first | second | |
| | Al Powder | frit | (glass/ | medium | Al Powder | frit | (glass/ | medium | aluminum | aluminum | ΔVoc |
| Ex.No | (w %) | (w %) | aluminum) | (w %) | (w %) | (w %) | aluminum) | (w %) | layer | layer | (%) |
| Ex.1 | 22.2 | 0.67 | 0.03 | 77.13 | 67.5 | 0 | 0 | 32.5 | 4.5 | 37 | 0.54 |
| Ex.2 | 22.7 | 1.36 | 0.06 | 75.94 | 67.5 | 0 | 0 | 32.5 | 4.5 | 37 | 0.78 |
| Ex.3 | 22.7 | 1.36 | 0.06 | 75.94 | 77.5 | 0.54 | 0.007 | 21.96 | 4.5 | 37 | 0.98 |
| Ex.4 | 22.7 | 2.72 | 0.12 | 74.58 | 67.5 | 0 | 0 | 32.5 | 4.5 | 37 | 1.09 |
| Ex.5 | 22.7 | 5.68 | 0.25 | 71.62 | 67.5 | 0 | 0 | 32.5 | 3.5 | 37 | 1.00 |
| Ex.6 | 22.7 | 11.35 | 0.5 | 65.95 | 67.5 | 0 | 0 | 32.5 | 3.5 | 37 | 0.79 |
| Ex.7 | 22.7 | 22.7 | 1.00 | 54.6 | 67.5 | 0 | 0 | 32.5 | 3.5 | 37 | 0.02 |

| | | | | | | | | |
|---|---|---|---|---|---|---|---|---|
| Co.Ex. | 78 | 0 | 0 | 22 | — | 42 | — | 0 |
| 1 | | | | | | | | (STD) |
| Co.Ex. | 22.7 | 1.36 | 0.06 | 75.94 | — | 4.5 | — | −4.92 |
| 2 | | | | | | | | |
| Co.Ex. | 69.2 | 8.3 | 0.12 | 22.5 | — | 42 | — | −0.08 |
| 3 | | | | | | | | |

What is claimed is:

1. A back-side aluminum electrode adjacenty formed on silicon wafer of p-type solar cell, comprising (a) first aluminum layer and (b) second aluminum layer,
wherein (a) first aluminum layer formed on the silicon wafer, formed from first aluminum paste comprises aluminum powder and glass frit,
wherein the weight ratio of the glass frit for the aluminum powder (glass/aluminum) is 0.02-1.0, and
wherein (b) second aluminum layer formed on the first aluminum layer, formed from second aluminum paste comprises at least aluminum powder,
wherein the weight ratio (glass/aluminum) of the second aluminum paste is less than the weight ratio (glass/aluminum) of the first aluminum paste.

2. The back-side electrode according to claim 1, wherein the thickness of the back-side aluminum electrode is equal to or more than 10.0 μm.

3. The back-side electrode according to claim 1, wherein the silicon wafer comprises passivation layer and silicon layer, and the passivation layer is deposited on the silicon layer.

4. The back-side electrode according to claim 1, wherein the glass frit is selected from the group consisting of B₂O₃—SiO₂—Bi₂O₃ based glass, and B₂O₃—SiO₂—PbO based glass.

5. The back-side electrode according to claim 1, wherein a glass transition temperature of the glass frit in both the first aluminum paste and the second aluminum paste is no more than 577° C.
